(19) United States
(12) Patent Application Publication
(10) Pub. No.: US 2015/0163913 A1
(43) Pub. Date: Jun. 11, 2015

(54) NESTED MODULE PACKAGE, AND METHOD FOR MANUFACTURING SAME

(71) Applicant: SAMSUNG ELECTRO-MECHANICS CO., LTD., Suwon-Si, Gyeonggi-Do (KR)

(72) Inventors: Eun Jung Jo, Suwon-Si (KR); Young Ho Sohn, Suwon-Si (KR); Jae Hyun Lim, Suwon-Si (KR)

(73) Assignee: SAMSUNG ELECTRO-MECHANICS CO., LTD., Suwon-Si, Gyeonggi-Do (KR)

(21) Appl. No.: 14/411,491

(22) PCT Filed: Jun. 28, 2013
(86) PCT No.: PCT/KR2013/005741

§ 371 Date: Dec. 27, 2014

(30) Foreign Application Priority Data
Jun. 29, 2012 (KR) 10-2012-0070668

(51) Int. Cl. H05K 1/18; H05K 3/30

(52) U.S. Cl. CPC H05K 1/18; H05K 3/306

(57) ABSTRACT

Disclosed herein is a superimposed module package, including: a printed circuit board; a first module electrically connected on the printed circuit board; and a second module superimposed between the printed circuit board and the first module to electrically connect the first module to the printed circuit board. According to the preferred embodiments of the present invention, the superimposed module package can secure the diversity of the product line-up by applying various combinations of the power module, the control module, the light emitting module, the storage module, and the like, to each module.

### CROSS REFERENCE TO RELATED APPLICATION

This application claims the benefit of Korean Patent Application No. 10-2012-0070688, filed on Jun. 29, 2012, entitled “Superimposed Module Package And Method Of Manufacturing The Same” which is hereby incorporated by reference in its entirety into this application.

### BACKGROUND OF THE INVENTION

1. Technical Field

The present invention relates to a superimposed module package and a method of manufacturing the same.

2. Description of the Related Art

With the development of power electronic industry, a demand for light, small, inexpensive, and powerful power system has increased.

In line with the tendency, as described in Korean Patent Laid-Open Publication No. 2001-0070014 (Laid-Open Published on Jul. 25, 2001), an intelligent semiconductor power module in which various power semiconductor chips are integrated in a single package and control circuit components for controlling the power semiconductor chips is included in the single package has been in the limelight from the related art.

However, according to the intelligent semiconductor power module according to the related, since a power unit and a control unit are installed in a single module, when components or a control device of the power unit is in a defective condition, the overall module is considered to be defective.

Therefore, since the overall module is discarded due to a failure in one of the components and the control device, economic loss is incurred.

### SUMMARY OF THE INVENTION

The present invention has been made in an effort to provide a superimposed module package capable of easily replacing a module including defective components or devices.

Further, the present invention has been made in an effort to provide a method of manufacturing a superimposed module package capable of easily replacing a module including defective components or devices.

According to a preferred embodiment of the present invention, there is provided a superimposed module package, including: a printed circuit board; a first module electrically connected on the printed circuit board; and a second module superimposed between the printed to circuit board and the first module to electrically connect the first module to the printed circuit board.

The printed circuit board may include a plurality of connection holes and pads, the second module may include first through holes corresponding to the connection holes, and the first module may include a plurality of lead frames which are inserted into the connection holes through the first through holes.

The superimposed module package may further include: a third module including second through holes corresponding to the connection holes of the printed circuit board and mounted on a lower surface of the printed circuit board.

The first module may be provided as a power module including an insulated gate bipolar transistor (IGBT) or a power metal oxide semiconductor field-effect transistor (MOSFET).

The first module may be provided as a light emitting module including a plurality of light emitting devices.

The second module may be provided as a control module including an IC or a control device which controls the first module.

The first module may further include a heat radiating unit including a heat sink mounted on an upper surface thereof by a conductive paste.

The third module may be provided as a storage module including a semiconductor memory device.

According to another preferred embodiment of the present invention, there is provided a method of manufacturing a superimposed module package, including: preparing a printed circuit board including a plurality of connection holes and pads; mounting a second module to engage first through holes with connection holes of the printed circuit board; and mounting the first module superimposing the second module by inserting lead frames into the connection holes through the first through holes of the second module.

The method of manufacturing a superimposed module package may further include: mounting a third module including second through holes corresponding to the connection holes of to the printed circuit board on a lower surface of the printed circuit board.

The connection hole of the printed circuit board may be formed in a form of a through hole or a blind via hole.

The preparing of the printed circuit board may include forming an inner layer circuit connected to the plurality of connection holes or pads.

The first module may be a power module or a light emitting module and the second module may be superimposed as a control module for controlling the first module.

The third module may be provided as a storage module including a semiconductor memory device.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exploded perspective view of a superimposed module package according to a preferred embodiment of the present invention;

FIG. 2 is a perspective view of the superimposed module package according to the preferred embodiment of the present invention; and

FIG. 3 is an exploded perspective view of a superimposed module package according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

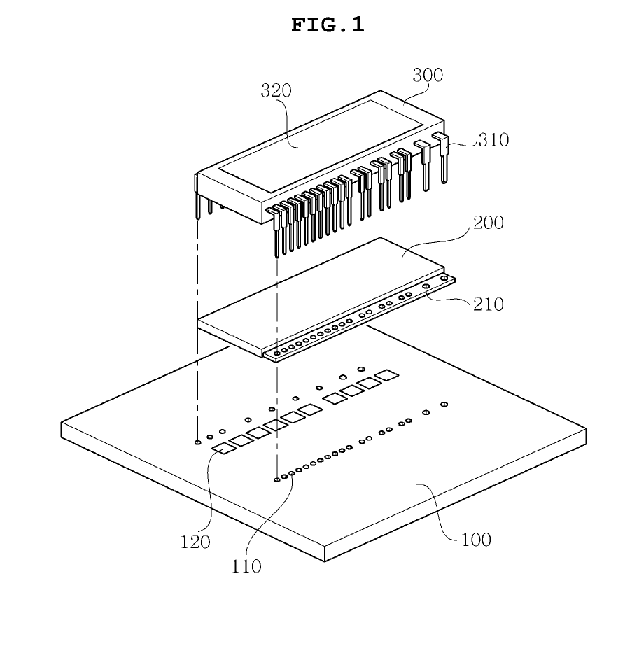

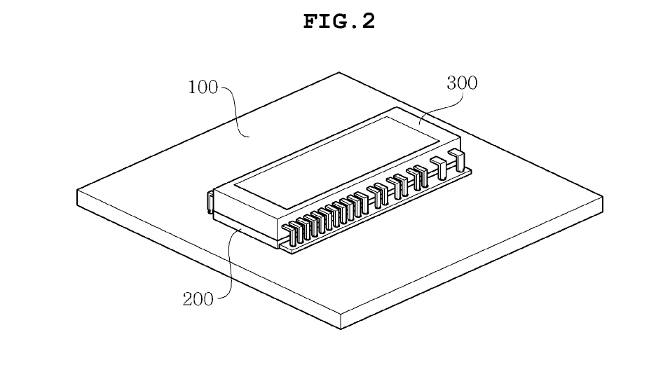

Hereinafter, preferred embodiments of the present invention will be described in detail with reference to the accompanying drawings. FIG. 1 is an exploded perspective view of a superimposed module package according to a preferred embodiment of the present invention and FIG. 2 is a perspective view of the superimposed module package according to the preferred embodiment of the present invention.

The superimposed module package according to the preferred embodiment of the present invention includes a printed circuit board 100, a first module 300 which is electrically connected on the printed circuit board 100, and a second module 200 which is superimposed between the printed circuit board 100 and the first module 300 and electrically connected therebetween.

The printed circuit board 100 is a printed circuit board on which a plurality of connection holes 110 and pads 120 are formed, in which the connection hole 110 may be inserted with a lead frame 310 of the first module 300 and the pad 120 may be provided to electrically connect to the second module 200 which is mounted on the printed circuit board 100.

The printed circuit board 100 includes an inner layer circuit which is connected to a plurality of connection holes 110 or pads 120, such that the plurality of connection holes 110 or pads 120 may be electrically connected to each other by the inner layer circuit. In this configuration, the printed circuit board 100 may include other electrical connection parts, such as a bump and a wire, in addition to the pad 120, to electrically connect to the second module 200.

The first module 300 is a power module which includes power devices, such as an insulated gate bipolar transistor (IGBT) and a power metal oxide semiconductor field-effect transistor (MOSFET) and includes a plurality of lead frames 310 which are inserted into each of the connection holes 110 of one side or both sides of the printed circuit board 100 and includes a heat radiating unit 320 including a heat sink mounted on an upper surface of the printed circuit board 100 by a conductive paste.

Further, the first module 300 may optionally include various modules, for example, a light emitting module including a plurality of light emitting devices, such as LED, in addition to the power module including the power device.

The second module 200 is a control module which includes an IC or a control device electrically connected to the first module 300 to control the first module 300 and is mounted on the printed circuit board 100 and includes a plurality of first through holes 210 on one side of the printed circuit board 100. The plurality of through holes 210 are formed corresponding to the connection holes 110 of the printed circuit board 100 and are provided to have each of the lead frames 310 of the first module 300 penetrate therethrough.

As illustrated in FIG. 2, the superimposed module package is configured so that the second module 200 is superimposed between the first module 300 and the printed circuit board 100, in which the second module 200 may control the first module 300 using the lead frames 310 connected by penetrating through the through holes 210.

Further, according to the superimposed module package according to the preferred embodiment of the present invention, the first module 300 and the second module 200 are separately manufactured to detect a defect of each module and then the first module 300 and the second module 200 in a normal state are electrically connected to each other through the lead frame 310 to be superimposedly packaged, thereby greatly reducing the manufacturing costs of the superimposed module package.

In particular, when the second module 200 is superimposedly mounted as the control module, it is sufficient to separate, modify, and again mount only the second module 200 without modifying the overall superimposed module package so as to add other functions to the control function. Similarly, the first module 300, not the second module 200, may be separated, modified, and again mounted to add other functions.

Therefore, the superimposed module package according to the preferred embodiment of the present invention may secure the diversity of the product line-up by applying various combinations, such as the power module, the control module, and the light emitting module, to the first module 300 and the second module 200.

Further, according to the superimposed module package according to the preferred embodiment of the present invention, the second module 200 such as the control module is superimposed in an empty space between the first module 300 and the printed circuit board 100, thereby implementing the package with the reduced size.

In this case, when the first module 300 is the power module which emits a considerable amount of heat, the second module 200 is superimposed, being spaced apart from the first module 300 at a predetermined distance, and therefore a malfunction of the first second module 200 due to heat reduces, thereby stably controlling the first module 300.

Hereinafter, a method of manufacturing a superimposed module package according to the preferred embodiment of the present invention will be described with reference to FIGS. 1 and 2.

According to the method of manufacturing a superimposed module package according to the preferred embodiment of the present invention, the printed circuit board 100 including the plurality of connection holes 110 and pads 120 is prepared.

As illustrated in FIG. 1, the printed circuit board 100 includes the connection hole 110 into which the lead frame 310 of the first module 300 is inserted and the pad 120 electrically connected to the second module 200.

In this case, the connection hole 110 may be provided in a form of the through hole penetrating through the printed circuit board 100 or a blind via hole (BVH).

After the printed circuit board 100 is prepared, the second module 200 is mounted so as to engage the first through hole 210 of the second module 200 with the connection hole 110 of the printed circuit board 100.

In detail, the first through hole 210 of the second module 200 is formed to have a circular aperture form having the same diameter as the connection hole 110 of the printed circuit board 100, and thus engaged with the connection hole 110.

Further, the mounting process of the second module 200 includes a process of being mounted on the surface of the printed circuit board 100 by a surface mounting technology (SMT) method and a process of electrically connecting the pad or the terminal of the second module 200 to the pad 120 of the printed circuit board 100.

After the second module 200 is mounted, the first module 300 is superimposedly mounted on the second module 200.

In detail, the lead frame 310 of the first module 300 is inserted into the connection hole 110 of the printed circuit board 100 through the first through hole 210 of the second module 200, such that the first module 300 is superimposedly mounted on the second module 200.

The method of manufacturing a superimposed module package according to the preferred embodiment of the present invention may simultaneously perform the process of mounting the second module 200 and the process of mounting the first module 300. That is, the second module 200 may be mounted in the state in which the lead frame 310 of the first module 300 is inserted into the connection hole 110 through the first through hole 210 of the second module 200.

Therefore, the method of manufacturing a superimposed module package according to the preferred embodiment of the present invention can obtain an effect of separating the first module 300 or the second module 200 and again mounting an alternative module so as to easily replace the first module 300 or the second module 200 with an alternative module having other additional functions.

Therefore, the method of manufacturing a superimposed module package according to the preferred embodiment of the present invention may secure the diversity of the product line-up by applying various combinations, such as the power module, the control module, and the light emitting module, to the first module 300 and the second module 200.

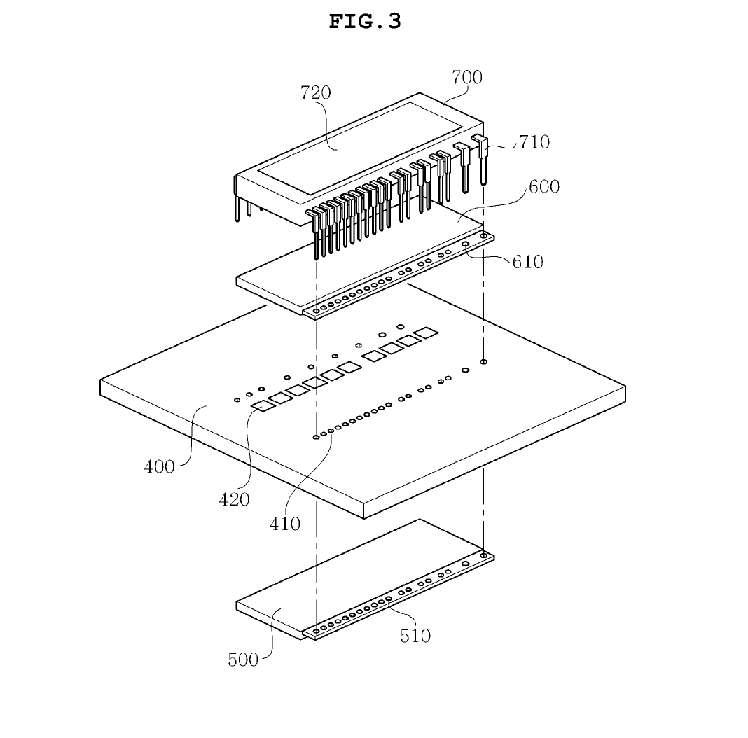

Hereinafter, a superimposed module package according to another preferred embodiment of the present invention will be described with reference to FIG. 3. FIG. 3 is an exploded perspective view of a superimposed module package according to another preferred embodiment of the present invention.

The superimposed module package according to another preferred embodiment of the present invention is similar to the superimposed module package according to the preferred embodiment of the present invention as described with reference to FIG. 1 but has a difference in that a third module 500 is additionally included on the lower surface of the printed circuit board 400. Therefore, in the description of the superimposed module package according to another preferred embodiment of the present invention, the same or similar portions of the superimposed module package according to the preferred embodiment of the present invention will be omitted.

The superimposed module package according to another preferred embodiment of the present invention includes a printed circuit board 400, a first module 700 which is electrically connected on an upper surface of the printed circuit board 400, a second module 600 which is superimposed between the printed circuit board 400 and the first module 700 and electrically connected therebetween, and the third module 500 which is electrically and additionally connected to the lower surface of the printed circuit board 400.

The third module 500, which is a storage module including a semiconductor memory device, such as a DRAM semiconductor memory, is mounted on the lower surface of the printed circuit board 400 corresponding to the second module 600 which is the control module and includes a second through hole 510 corresponding to the connection hole 410 on one side or both sides of the printed circuit board 400.

Optionally, the third module 500 has other electrical connection parts, such as a pad, bump, and a wire for the separately electrical connection to the printed circuit board 400 disposed on one side thereof and may be electrically connected to the printed circuit board 400.

The lead frames 710 of the first module 700 penetrating through the connection holes 410 of the printed circuit board 400 each penetrate through the second through holes 510 of the third module 500.

Therefore, the superimposed module package according to the preferred embodiment of the present invention may be implemented to be superimposed by combining modules having various functions, such as the power module, the control module, and the light emitting module, with the first module 700 to the third module 500.

Therefore, the superimposed module package according to another preferred embodiment of the present invention is applied by superimposing the plurality of modules, thereby providing more various combinations of the product line-up.

According to the preferred embodiments of the present invention, the superimposed module package can secure the diversity of the product line-up by applying various combinations of the power module, the control module, the light emitting module, the storage module, and the like, to each module.

Further, according to the preferred embodiments of the present invention, the method of manufacturing a superimposed module package can separate the modules and again install the alternative module so as to easily replace each module with the alternative module.

Although the preferred embodiments of the present invention have been disclosed for illustrative purposes, they are for specifically explaining the present invention and thus a linear vibration motor according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A superimposed module package, comprising:
a printed circuit board;
a first module electrically connected on the printed circuit board; and
a second module superimposed between the printed circuit board and the first module to electrically connect the first module to the printed circuit board.

2. The superimposed module package as set forth in claim 1, wherein the printed circuit board includes a plurality of connection holes and pads,
the second module includes first through holes corresponding to the connection holes, and
the first module includes a plurality of lead frames which are inserted into the connection holes through the first through holes.

3. The superimposed module package as set forth in claim 2, further comprising:
a third module including second through holes corresponding to the connection holes of the printed circuit board and mounted on a lower surface of the printed circuit board.

4. The superimposed module package as set forth in claim 1, wherein the first module is provided as a power module including an insulated gate bipolar transistor (IGBT) or a power metal oxide semiconductor field-effect transistor (MOSFET).

5. The superimposed module package as set forth in claim 1, wherein the first module is provided as a light emitting module including a plurality of light emitting devices.

6. The superimposed module package as set forth in claim 1, wherein the second module is provided as a control module including an IC or a control device which controls the first module.

7. The superimposed module package as set forth in claim 1, wherein the first module further includes a heat radiating unit including a heat sink mounted on an upper surface thereof by a conductive paste.

8. The superimposed module package as set forth in claim 3, wherein the third module is provided as a storage module including a semiconductor memory device.

9. A method of manufacturing a superimposed module package, comprising:
preparing a printed circuit board including a plurality of connection holes and pads;
mounting a second module to engage first through holes with connection holes of the printed circuit board; and
mounting the first module superimposing the second module by inserting lead frames into the connection holes through the first through holes of the second module.

10. The method as set forth in claim 9, further comprising:
mounting a third module including second through holes corresponding to the connection holes of the printed circuit board on a lower surface of the printed circuit board.

11. The method as set forth in claim 9, wherein the connection hole of the printed circuit board is formed in a form of a through hole or a blind via hole.

12. The method as set forth in claim 9, wherein the preparing of the printed circuit board includes forming an inner layer circuit connected to the plurality of connection holes or pads.

13. The method as set forth in claim 9, wherein the first module is a power module or a light emitting module and the second module is superimposed as a control module for controlling the first module.

14. The method as set forth in claim 10, wherein the third module is provided as a storage module including a semiconductor memory device.
